(19) United States
(12) Patent Application Publication
(10) Pub. No.: US 2002/0014650 A1
(43) Pub. Date: Feb. 7, 2002

(54) High frequency transistor device

(76) Inventor: Hirotoshi Kubo, Gunma (JP)

Correspondence Address: WENDEROTH, LIND & PONACK, L.L.P., 2033 K STREET N. W., SUITE 800, WASHINGTON, DC, 20006-1021, US

(21) Appl. No.: 09/919,797

(22) Filed: Aug. 2, 2001

Related U.S. Application Data
(62) Division of application No. 09/517,698, filed on Mar. 2, 2000, now abandoned.

(30) Foreign Application Priority Data
Mar. 3, 1999 (JP) 55895/1999

(51) Int. Cl. H01L 29/76

(52) U.S. Cl. 257/309

(57) ABSTRACT

A semiconductor device includes a base region of a first conductivity type formed on a top surface of a collector layer of a second conductivity type, and the first conductivity type is opposite the second conductivity type. A groove is formed in the surface of the base region, and an emitter region of the second conductivity type is formed in the surface of the base region at the bottom of the groove. Thereby, fine base width W_{b} and low base resistance r_{b} are obtained.

This application is a Divisional Application of Ser. No. 09/517,698, filed Mar. 2, 2000.

### BACKGROUND OF THE INVENTION

1. Field of the Invention

The present invention relates to a high-frequency transistor device and a method for manufacturing the same.

2. Description of the Prior Art

FIG. 1 shows a typical structure of a planar high-frequency npn transistor. As shown in the diagram, an n-type collector layer 2 is provided with a n+-type semiconductor layer 1. A p-type base region 3 is formed in the surface of the collector layer 2. An n+-type emitter region 4 is formed in the surface of the base region 3. The top surface is coated with a silicon oxide film 5, which is an insulating film. Contact holes are formed in the silicon oxide film 5. A base electrode 6 and an emitter electrode 7 are formed on the silicon oxide film 5 and connected to the base region 8 and emitter region 4 respectively through the contact holes. Since the high-frequency properties of the transistor depend mainly on the base width W_{b}, a graft base structure is employed. The graft base structure comprises a p+-type extrinsic base region 8 formed around the emitter region 4. This configuration not only achieves a narrow base width W_{b}, but also relaxes the depletion layer curve across the base-collector junction and reduces the base resistance.

A shallow emitter junction is also indispensable for obtaining a shallow base width W_{b}. For this reason, the emitter region 4 is formed through impurity diffusion from a doped polysilicon layer 9, as described in Japanese Laid-Open Patent Publication No. 7-142497, for example.

However, the base region 3 and extrinsic base region 8 in the graft base structure of FIG. 1 are formed by ion implantation and thermal diffusion of impurities, and therefore require two photoetching technologies. Hence, it is extremely difficult to simplify the process further. Further, since the base region 3 is formed through thermal diffusion of impurities, the depth of the diffusion is frequently uneven, resulting in large variations in high-frequency properties.

It is also difficult to obtain a shallow junction because the base is formed by thermal diffusion. Since the impurity concentration must be set low in order to obtain a shallow junction, the base resistance r_{b} tends to be large.

### SUMMARY OF THE INVENTION

In view of the foregoing shortcomings, it is an object of the present invention to provide an improved transistor having excellent high-frequency properties.

To achieve the above object, there is provided a semiconductor device, which comprises a base region of a second conductivity type formed on a top surface of a collector layer of a first conductivity type, and the first conductivity type is opposite the second conductivity type. A groove is formed in the top surface of the base region, and an emitter region of the first conductivity type is formed in the base region at the bottom surface of the groove.

Thereby, precise base width W_{b} and low base resistance r_{b} are obtained.

The above and other objects, features, and advantages of the present invention will become apparent from the following description when taken in conjunction with the accompanying drawings which illustrate preferred embodiments, of the present invention by way of example.

### BRIEF DESCRIPTION OF THE DRAWINGS

FIG. 1 is a cross-sectional diagram showing the conventional structure of a semiconductor device;

FIG. 2 is a cross-sectional diagram showing an embodiment of a semiconductor device according to the present invention; and

FIGS. 3A, 3B, 3C, 4A, 4B, 4C, 5A and 5B are cross-sectional diagrams showing the steps of manufacturing a semiconductor device according to an embodiment of the present invention.

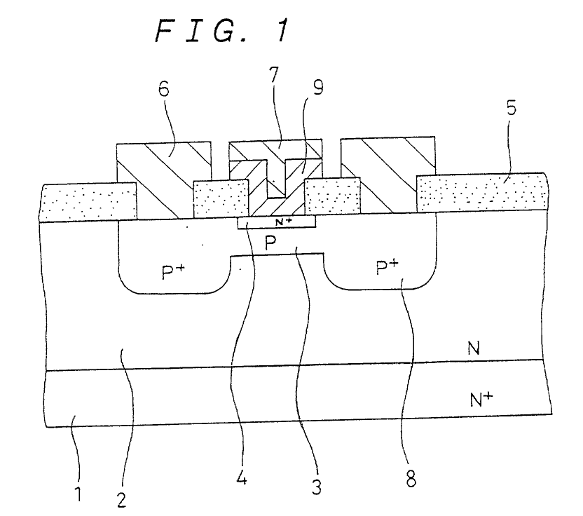

### DETAILED DESCRIPTION OF THE PREFERRED EMBODIMENTS

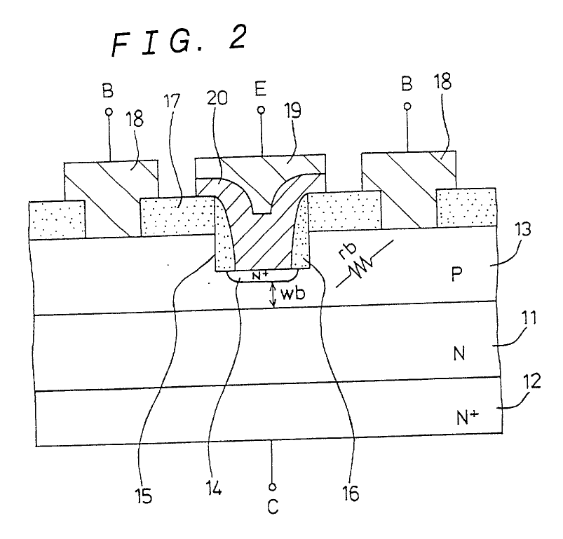

An embodiment of the semiconductor device and method of manufacturing the same of the present invention will be described below, while referring to the accompanying drawings. FIG. 2 is a cross-sectional diagram showing an npn transistor device according to the present invention.

As shown in FIG. 2, the npn transistor device comprises a semiconductor layer serving as a collector, which is formed on an n+-type semiconductor substrate 12. A p-type base region 13 is formed as an epitaxial layer on the surface of the layer 11 so as to have a substantially flat bottom surface, as shown in FIG. 2. A groove 15 is formed in a portion of the base region 13, and an n+-type emitter region 14 is formed in the base region 13 at the bottom surface of groove 15. Spacers 16 cover the sidewalls of the groove 15. A silicon oxide film 17 covers the surface of the base region 13. Base electrodes 18 contact the surface of the base region 13 through contact holes formed in the silicon oxide film 17. The transistor device is also provided with an emitter electrode 19 and a polycrystalline silicon layer 20 forming a portion of the emitter electrode 19 and serving as the diffusion source for the emitter region 14. The base electrode 18 and the emitter electrode 19 are formed as an aluminum layer.

The base region 13 comprises either a diffusion region formed by thermal diffusion at a prescribed diffusion depth or a semiconductor layer formed on the surface of the layer 11 by vapor deposition and having a uniform distribution of impurity concentration in the vertical direction of the layer. The thickness of the base region 13 is approximately 1.0 μm. The groove 15 is formed by etching into the base region 13 and has a width of approximately 0.5 μm and a depth from the top surface of the base region 13 of about 0.7 μm. The p-type base region 13 is exposed at the bottom of the groove 15. The emitter region 14 is formed at the bottom surface of the groove 15 at a diffusion depth of approximately 0.1 μm.

The spacers 16 comprise an insulating film such as a non-doped silicon oxide film, or the like, and cover the sidewalls of the groove 15 at a thickness of approximately 0.1 μm. Accordingly, when the groove 15 forms a hole with a square opening 0.5×0.5 μm and the spacers 16 are formed on the side walls of the groove 15, a portion of the base region 13 is exposed on the bottom of the groove 15 at 0.3×0.3 μm.

Assuming the groove 15 of depth 0.7 μm and the emitter region 14 of depth 0.1 μm are formed in the base region 13 of depth 1.0 μm, the base width W_{b} (width between emitter region 14 and the bottom surface of base region 13) of this transistor is approximately 0.2 μm. Hence, by forming an emitter region 14 in the bottom of the groove 15, it is possible to determine the base width W_{b} according to the depth of the groove 15. Instead of being required to reduce the impurity concentration in order to acquire an extremely shallow junction by thermal diffusion, formation of the groove 15 makes it possible to increase the impurity concentration in the base region 13, enabling the base region 13 to be formed as a single region (i.e., free of graft structures). As a result, it is possible to eliminate one step of the diffusion process. Further, since a relatively high impurity concentration can be given in the base region 13, it is possible to reduce the base resistance r_{b} between the active region of the base and the base electrodes 18.

When forming the base region with an epitaxial layer, there is an unevenness of approximately 10% in the thickness of the base region and a nonuniformity of about 10% in the depth of the groove 15 formed by etching, resulting in an unevenness in the base width W_{b} of 14-20%. In comparison to the approximately 30% variation in the base width W_{b} formed by the conventional method of ion implantation and thermal diffusion, this value shows that the structure of the present invention can greatly reduce variation.

Next, the manufacturing method for a semiconductor device of the present invention will be described.

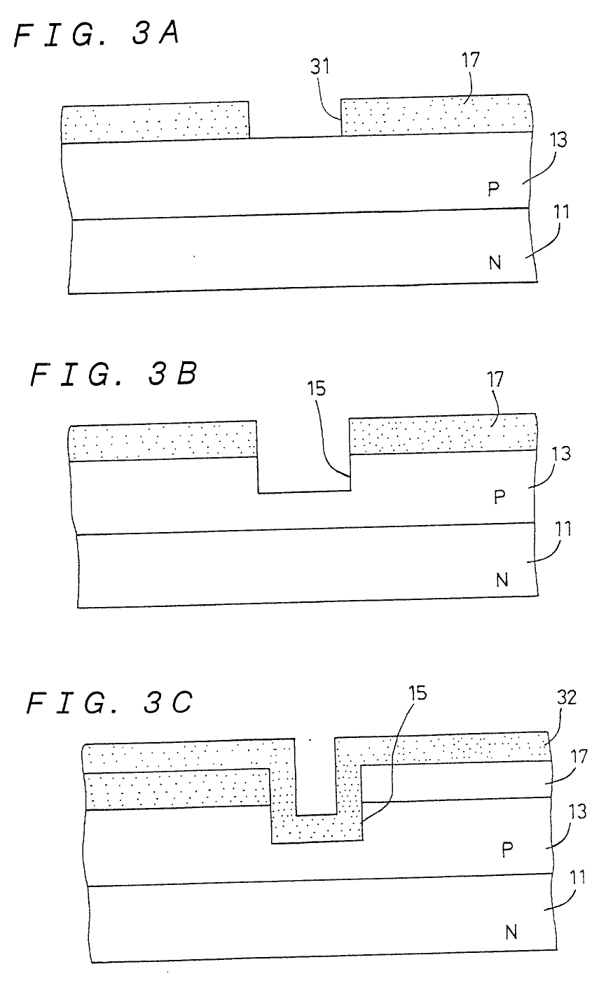

Step 1: referring to FIG. 3A.

First, the n-type substrate 11 is prepared. A highly concentrated semiconductor layer 12 (not shown) is provided on the underside of the substrate 11 and serves as a collector. The top surface of the substrate 11 is cleaned and a p-type epitaxial layer that serves as the base region 13 is formed over the entire surface of the substrate 11 by vapor deposition.

The silicon oxide film 17 having a thickness of approximately 5000 Å is formed on top of the base region 13. A hole 31 is formed in the silicon oxide film 17 using normal photoetching technologies.

Step 2: referring to FIG. 3B

Anistropic etching is conducted to etch the groove 15 into the base region 13 using the silicon oxide film 17 as a mask. As described above, the etching depth of the groove 15 determines the base width W_{b}.

Step 3: referring to FIG. 3C.

An NSG film (non-doped silicon oxide film) 32, having a thickness of 8000 Å is formed over the entire top surface of the device using low pressure chemical vapor deposition (LPCVD). At the same time, the NSG film 32 becomes embedded in the groove 15.

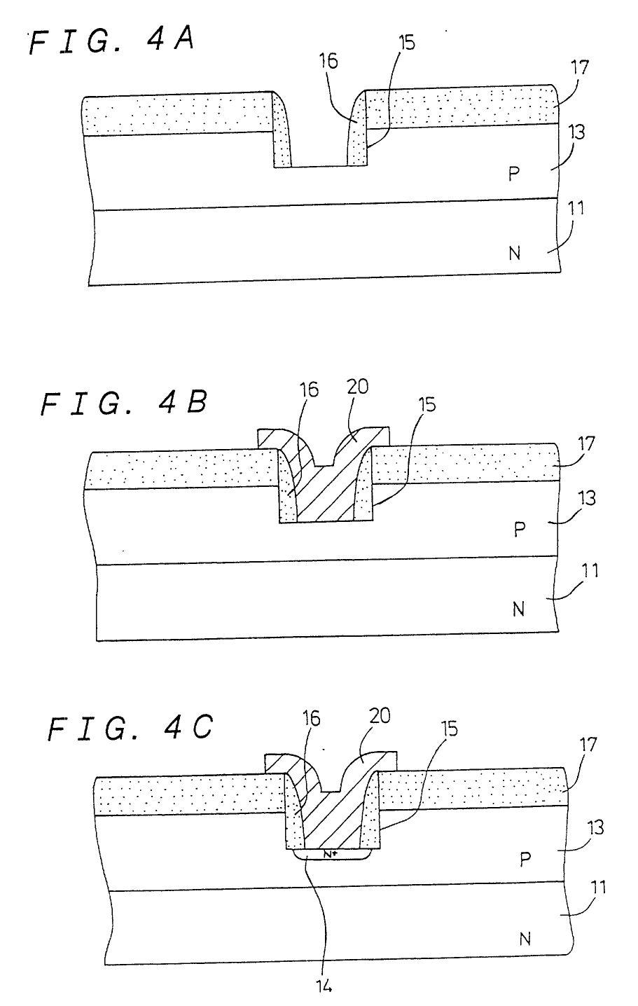

Step 4: referring to FIG. 4A.

The NSG film 32 is etched by using anistropic etching until the base region 13 is exposed on the bottom of the groove 15, thereby forming spacers 16 on the side walls of the groove 15.

Step 5: referring to FIG. 4B.

A polycrystalline silicon layer 20 is formed over the entire top surface of the device by using chemical vapor deposition (CVD) method. The polycrystalline silicon layer 20 is deposited inside the groove 15 and contacts the top surface of the base region 13. Arsenic ions are implanted by using ion implantation in the entire top surface of the polycrystalline silicon layer 20 for emitter diffusion. The polycrystalline silicon layer 20 is etched according to a pattern using normal photoetching technologies, leaving only a portion of the polycrystalline silicon layer 20 positioned over the groove 15 and removing the rest.

Step 6: referring to FIG. 4C.

Heat between 900 and 1000° C. is applied to the entire wafer for 0.5-2 hours, causing arsenic impurities to be diffused from the polycrystalline silicon layer 20 into base region 13 so as to form the emitter region 14. Since the side walls of the groove 15 are covered with the spacers 16, it is possible to limit the diffusion area to only the bottom of the groove 15.

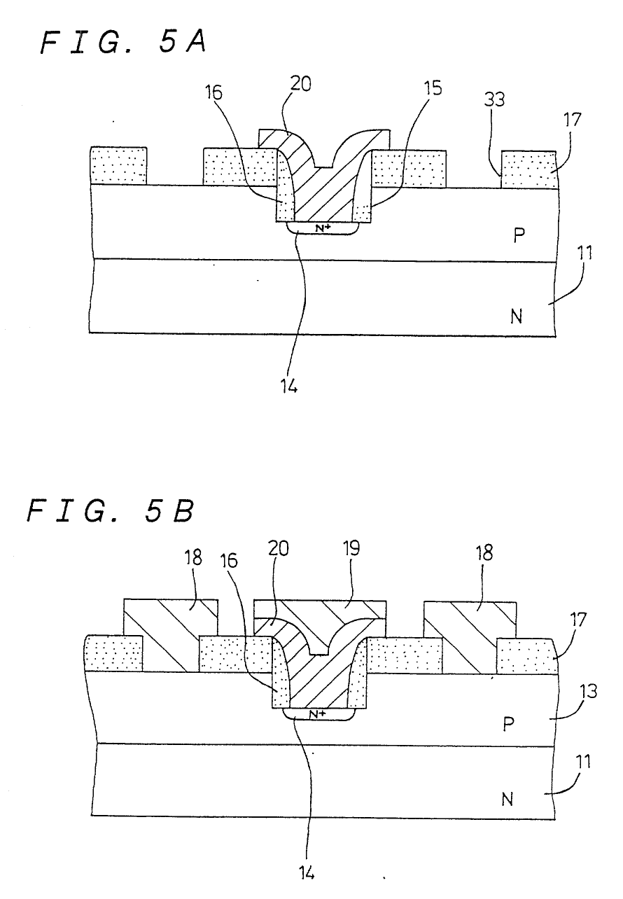

Step 7: referring to FIG. 5A.

Photoetching technologies are employed on the silicon oxide film 17 to form contact holes 33. The contact holes 33 expose the top surface of the base region 13.

Step 8: referring to FIG. 5B.

An aluminum layer is formed over the entire top surface using sputtering or vapor deposition. This aluminum layer is then etched using photoetching technologies to form the base electrodes 18 and emitter electrodes 19.

In the process described above, the only thermal process required for manufacturing the transistor device of the present invention is an emitter diffusion thermal process. Therefore, it is possible to reduce the number of thermal processes, which are required to manufacture a transistor, thereby reducing the unevenness of the performances of the transistor device. Further, by using the spacers 16, it is possible to form a groove 15 even more finely than the limitation, which is formed by using photoetching technologies. Accordingly, it is possible to obtain a transistor device having superior high-frequency properties.

Although the present embodiment describes an npn transistor device, it is also possible to reverse the conductivity of the device and manufacture a pnp-type transistor.

As described in the embodiment above, the present invention employs the groove 15 in the base region to obtain a precise base width W_{b}. As a result, it is possible to obtain an improved transistor having excellent high-frequency properties.

In addition to achieving a more precise base width W_{b} than conventional methods, the manufacturing method of the present invention removes the necessity of forming the conventional extrinsic base region. Accordingly, the manufacturing process can be simplified to reduce the steps of the process, and the present invention provides advantages to produce a transistor device having a low base resistance r_{b}.

Although a certain preferred embodiment of the present invention has been shown and described in detail, it should be understood that various changes and modifications may be made therein without departing from the scope of the appended claims.

What is claimed is:

1. A method of manufacturing a semiconductor device, comprising:
forming a collector layer of a first conductivity type;
forming a base region of a second conductivity type formed on a top surface of said collector layer of said first conductivity type, said first conductivity type being opposite said second conductivity type,
said base region being formed as a single region having uniform depth thereof,
forming a groove in a top surface of said base region at a portion thereof; and
forming an emitter region of said first conductivity type in said base region at a bottom surface of said groove.

2. A method of manufacturing a semiconductor device according to claim 1, wherein said base region on said top surface of said collector layer is formed by using an epitaxial growth technology.

3. A method of manufacturing a semiconductor device according to claim 1, wherein said base region is formed on said top surface of said collector layer by a diffusion of impurities at a prescribed diffusion depth.

4. A method of manufacturing a semiconductor device according to claim 1, wherein said base region has a flat bottom surface beneath said emitter region and beneath a base electrode.

5. A method of manufacturing a semiconductor device according to claim 1, further comprising:
forming spacers on sidewalls in said groove;
forming a diffusion source film in said bottom surface of said groove to be embedded therein between said spacers; and
forming said emitter region of said first conductivity type formed in said top surface of said base region at a bottom of said diffusion source film between said spacers.

6. A method of manufacturing a semiconductor device according to claim 5, further comprising:
forming a base electrode on said top surface of said base region around said portion of said groove; and
an emitter electrode on said surface of said diffusion source film.

7. A method of manufacturing a semiconductor device according to claim 6, wherein said base electrode and said emitter electrode are formed of aluminum material.

8. A method of manufacturing a semiconductor device according to claim 1, wherein said diffusion source film is a polycrystalline silicon layer having impurities for emitter diffusion.
